(19) United States
(12) Patent Application Publication
(10) Pub. No.: US 2026/0359965 A1
(43) Pub. Date: Nov. 12, 2026

(54) SYSTEMS, METHODS, AND SOFTWARE FOR OVERLAY MODEL BUILDING AND APPLICATION

(71) Applicant: ASML NETHERLANDS B.V., Veldhoven (NL)

(72) Inventors: Jiyou FU, San Jose, CA (US); Chenyu ZHANG, Fremont, CA (US)

(73) Assignee: ASML NETHERLANDS B.V., Veldhoven (NL)

(21) Appl. No.: 19/122,483

(22) PCT Filed: Oct. 13, 2023
(86) PCT No.: PCT/EP2023/078530

§ 371 Date: Apr. 18, 2025

Related U.S. Application Data
(60) Provisional application No. 63/424,065, filed on Nov. 9, 2022.

(51) Int. Cl. G06T 7/00; G06T 5/50; G06V 10/25

(52) U.S. Cl. CPC G06T 7/0006; G06T 5/50; G06T 7/001; G06V 10/25; G06T 2207/10061; G06T 2207/20221; G06T 2207/30148

(57) ABSTRACT

Systems, methods, and computer software are disclosed for determining overlays. One method can include performing a component analysis on a set of Scanning Electron Microscope (SEM) images to obtain coefficients of one or more selected components, where the set of SEM images comprises a multi-layer image. The overlay (OVL) can be determined for the multi-layer image based on the coefficients.

### CROSS-REFERENCE TO RELATED APPLICATION

This application claims priority of U.S. application 63/424,065 which was filed on 9 Nov. 2022, and which is incorporated herein in its entirety by reference.

### TECHNICAL FIELD

The description herein relates generally to metrology of patterns produced by lithographic processes. More particularly, the disclosure includes apparatus, methods, and computer programs for a determining the overlay of patterns from images.

### BACKGROUND

In manufacturing processes of integrated circuits (ICs), unfinished or finished circuit components are inspected to ensure that they are manufactured according to design and are free of defects. Inspection systems utilizing optical microscopes or charged particle (e.g., electron) beam microscopes, such as a scanning electron microscope (SEM) can be employed. As the physical sizes of IC components continue to shrink, and their structures continue to become more complex, accuracy and throughput in defect detection and inspection become more important. The overall image quality depends on a combination of high secondary-electron and backscattered-electron signal detection efficiencies, among others. Backscattered electrons have higher emission energy to escape from deeper layers of a sample, and therefore, their detection may be desirable for imaging of complex structures such as buried layers, nodes, high-aspect-ratio trenches or holes of 3D NAND devices. For applications such as overlay metrology, it may be desirable to obtain high quality imaging and efficient collection of surface information from secondary electrons and buried layer information from backscattered electrons, simultaneously, highlighting a need for using multiple electron detectors in a SEM. The ability to monitor and detect IC non-idealities may be limited by an image quality of the inspection system, including by the alignment or calibration of an SEM system.

### SUMMARY

In one aspect, a method includes performing a component analysis on a set of Scanning Electron Microscope (SEM) images to obtain coefficients of one or more selected components, where the set of SEM images comprises a multi-layer image. The method also includes determining an overlay (OVL) for the multi-layer image based on the coefficients.

In some variations, the OVL can be determined with a polynomial function of the coefficients of the one or more selected components or with a lookup table containing coefficients of the one or more selected components.

In other variations, the component analysis can be a Principal Component Analysis (PCA) or an Independent Component Analysis (ICA). The component analysis can be along a direction of the OVL in the multi-layer image. The component analysis can be of a two-dimensional multi-layer image.

In some variations, unit cells can be determined in the multi-layer image that represent a repeating portion of the multi-layer image. The multi-layer image can be generated by averaging intensities of the multi-layer image in the unit cells. The coefficients can be obtained in a region of interest of the SEM image, the region of interest having a lower noise contribution than other regions in the multi-layer image.

In other variations, principal components and their variances of the multi-layer image can be determined. The selected components can be the principal components having a largest variance and one or more successively lower variances. The selected components can be responsible for component variances at least 95% of the multi-layer image. The selected components can include a second principal component, which is a next most dominant component after a first principal component that is the dominant principal component.

In some variations, a method can include building an OVL model to determine the OVL based on the coefficients, the building comprising fitting a function to determine parameters of the function based on values of the selected components at different OVLs. The function can be an odd order polynomial, a third order polynomial, or a fifth order polynomial.

In yet other variations, a method can include obtaining multi-layer images, determining the coefficients from the component analysis for the multi-layer images, obtaining the different OVLs for the multi-layer images, and generating the OVL model based on the coefficients and the different OVLs. In some variations, a method can include applying the OVL model by: obtaining a test SEM image, determining test coefficients for the test SEM image by performing component analysis on the test SEM image, and determining a test OVL for the test SEM image based on applying the OVL model with the test coefficients.

In some variations, a method can include assigning weights to the coefficients. The weights can be determined based on an intensity level of the one or more selected components. The method can include applying the OVL model by: obtaining a test SEM image, determining test coefficients for the test SEM image by performing component analysis on the test SEM image, assigning test weights to the test coefficients, and determining a test OVL for the test SEM image based on applying the OVL model with the test coefficients and the test weights.

In other variations, a method can include fitting functions to the coefficients of the one or more selected components, where the OVL model can be generated based on the coefficients, the different OVLs, and the functions. The method can include applying the OVL model by: obtaining a test SEM image, determining test coefficients for the test SEM image by performing component analysis on the test SEM image, inputting the test coefficients into the functions, and determining a test OVL for the test SEM image based on applying the OVL model with the functions.

In some variations, a method can include determining an intercept search range, determining interpolated coefficients by interpolating the coefficients of coefficient curves for the selected components at intercept values in the intercept search range, generating assembled images based on the interpolated coefficients, the assembled images having corresponding OVL shifts, determining an OVL shift based on the assembled images, and modifying the OVL for the multi-layer image based on the OVL shift. The interpolated coefficients at the intercept values can be determined by interpolating over the coefficients within the intercept search range of the OVL shifts.

In other variations, determining of the OVL shift comprising can include selecting first regions and second regions of the assembled images, the first regions and second regions being of equal extents about respective centers of the assembled images, determining asymmetry scores of the assembled images, and setting the OVL shift based on the assembled image with the lowest asymmetry score.

In yet other variations, a method can include generating a template image for the multi-layer image, the template image generated to have an OVL shift of zero, comparing the template image to the assembled images, setting the OVL shift to be the corresponding OVL shift for the assembled image that is a best match to the template image. The best match can be determined by template matching or image differencing.

In some variations, a method can include obtaining an SEM test image, determining test coefficients of the SEM test image based on the one or more selected components, and determining an OVL of the test image based on applying OVL model with the test coefficients. The test coefficients can be determined based on linear regression of an SEM test image and the selected components.

### BRIEF DESCRIPTION OF THE DRAWINGS

The accompanying drawings, which are incorporated in and constitute a part of this specification, show certain aspects of the subject matter disclosed herein and, together with the description, help explain some of the principals associated with the disclosed implementations. In the drawings,

FIG. 1 is a schematic diagram illustrating an exemplary electron beam inspection (EBI) system, according to an embodiment of the present disclosure.

FIG. 2 is a schematic diagram of an exemplary electron beam tool, according to an embodiment of the present disclosure.

FIG. 3 depicts a schematic representation of holistic lithography, representing a cooperation between three technologies to optimize semiconductor manufacturing, according to an embodiment of the present disclosure.

FIG. 4 illustrates an exemplary SEM image of a printed pattern having an overlay between two layers, according to an embodiment of the present disclosure.

FIG. 5 illustrates performing principal component analysis (PCA) on an SEM image, according to an embodiment of the present disclosure.

FIG. 6 illustrates determining an overlay based on principal component analysis, according to an embodiment of the present disclosure.

FIG. 7 illustrates a process flow diagram for building an overlay model, according to an embodiment of the present disclosure.

FIG. 8 illustrates regions of interest utilized in determining coefficients for an OVL model, according to an embodiment of the present disclosure.

FIG. 9A is a diagram illustrating an overlay shift, according to an embodiment of the present disclosure.

FIG. 9B is a process flow diagram illustrating determining an overlay shift, according to an embodiment of the present disclosure.

FIG. 10 illustrates generating assembled images having respective overlay shifts, according to an embodiment of the present disclosure.

FIG. 11 illustrates determining an overlay shift based on asymmetries in symmetric assembled images, according to an embodiment of the present disclosure.

FIG. 12 illustrates determining an overlay shift based on asymmetric assembled images, according to an embodiment of the present disclosure.

FIG. 13 is a process flow diagram illustrating application of an OVL model, according to an embodiment of the present disclosure.

FIG. 14 is a block diagram of an example computer system, according to an embodiment of the present disclosure.

### DETAILED DESCRIPTION

Embodiments of the present disclosure are described in detail with reference to the drawings, which are provided as illustrative examples of the disclosure so as to enable those skilled in the art to practice the disclosure. Notably, the figures and examples below are not meant to limit the scope of the present disclosure to a single embodiment, but other embodiments are possible by way of interchange of some or all of the described or illustrated elements. Moreover, where certain elements of the present disclosure can be partially or fully implemented using known components, only those portions of such known components that are necessary for an understanding of the present disclosure will be described, and detailed descriptions of other portions of such known components will be omitted so as not to obscure the disclosure. Embodiments described as being implemented in software should not be limited thereto, but can include embodiments implemented in hardware, or combinations of software and hardware, and vice-versa, as will be apparent to those skilled in the art, unless otherwise specified herein. In the present specification, an embodiment showing a singular component should not be considered limiting; rather, the disclosure is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present disclosure encompasses present and future known equivalents to the known components referred to herein by way of illustration.

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “wafer” or “die” in this text should be considered as interchangeable with the more general terms “substrate” and “target portion”, respectively.

A patterning device can comprise, or can form, one or more patterns. The patterns can be generated utilizing CAD (computer-aided design) programs, based on a pattern or design layout, this process often being referred to as EDA (electronic design automation).

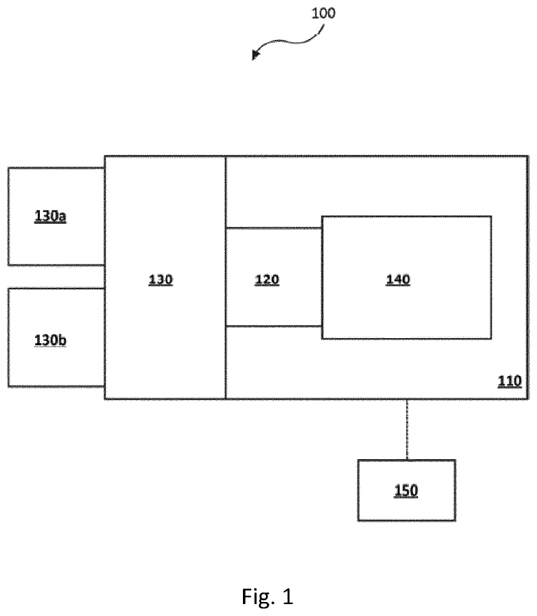

Reference is now made to FIG. 1, which illustrates an exemplary electron beam inspection (EBI) system 100 consistent with embodiments of the present disclosure. As shown in FIG. 1, EBI system 100 includes a main chamber 110, a load-lock chamber 120, an electron beam tool 140, and an equipment front end module (EFEM) 130. Electron beam tool 140 is located within main chamber 110. The exemplary EBI system 100 may be a single or multi-beam system. While the description and drawings are directed to an electron beam, it is appreciated that the embodiments are not used to limit the present disclosure to specific charged particles.

EFEM 130 includes a first loading port 130a and a second loading port 130b. EFEM 130 may include additional loading port(s). First loading port 130a and second loading port 130b receive wafer front opening unified pods (FOUPs) that contain wafers (e.g., semiconductor wafers or wafers made of other material(s)) or samples to be inspected (wafers and samples are collectively referred to as “wafers” hereafter). One or more robot arms (not shown) in EFEM 130 transport the wafers to load-lock chamber 120.

Load-lock chamber 120 is connected to a load/lock vacuum pump system (not shown), which removes gas molecules in load-lock chamber 120 to reach a first pressure below the atmospheric pressure. After reaching the first pressure, one or more robot arms (not shown) transport the wafer from load-lock chamber 120 to main chamber 110. Main chamber 110 is connected to a main chamber vacuum pump system (not shown), which removes gas molecules in main chamber 110 to reach a second pressure below the first pressure. After reaching the second pressure, the wafer is subject to inspection by electron beam tool 140. In some embodiments, electron beam tool 140 may comprise a single-beam inspection tool.

Controller 150 may be electronically connected to electron beam tool 140 and may be electronically connected to other components as well. Controller 150 may be a computer configured to execute various controls of EBI system 100. Controller 150 may also include processing circuitry configured to execute various signal and image processing functions. While controller 150 is shown in FIG. 1 as being outside of the structure that includes main chamber 110, load-lock chamber 120, and EFEM 130, it is appreciated that controller 150 can be part of the structure.

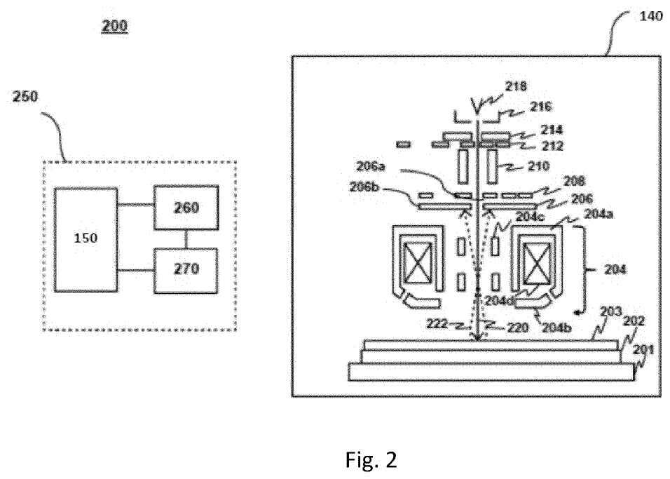

FIG. 2 illustrates schematic diagram of an exemplary imaging system 200 according to embodiments of the present disclosure. Electron beam tool 140 of FIG. 2 may be configured for use in EBI system 100. Electron beam tool 140 may be a single beam apparatus or a multi-beam apparatus. As shown in FIG. 2, electron beam tool 140 includes a motorized sample stage 201, and a wafer holder 202 supported by motorized sample stage 201 to hold a wafer 203 to be inspected. Electron beam tool 140 further includes an objective lens assembly 204, an electron detector 206 (which includes electron sensor surfaces 206a and 206b), an objective aperture 208, a condenser lens 210, a beam limit aperture 212, a gun aperture 214, an anode 216, and a cathode 218. Objective lens assembly 204, in some embodiments, may include a modified swing objective retarding immersion lens (SORIL), which includes a pole piece 204a, a control electrode 204b, a deflector 204c, and an exciting coil 204d. Electron beam tool 140 may additionally include an Energy Dispersive X-ray Spectrometer (EDS) detector (not shown) to characterize the materials on wafer 203.

A primary electron beam 220 is emitted from cathode 218 by applying a voltage between anode 216 and cathode 218. Primary electron beam 220 passes through gun aperture 214 and beam limit aperture 212, both of which may determine the size of electron beam entering condenser lens 210, which resides below beam limit aperture 212. Condenser lens 210 focuses primary electron beam 220 before the beam enters objective aperture 208 to set the size of the electron beam before entering objective lens assembly 204. Deflector 204c deflects primary electron beam 220 to facilitate beam scanning on the wafer. For example, in a scanning process, deflector 204c may be controlled to deflect primary electron beam 220 sequentially onto different locations of top surface of wafer 203 at different time points, to provide data for image reconstruction for different parts of wafer 203. Moreover, deflector 204c may also be controlled to deflect primary electron beam 220 onto different sides of wafer 203 at a particular location, at different time points, to provide data for stereo image reconstruction of the wafer structure at that location. Further, in some embodiments, anode 216 and cathode 218 may be configured to generate multiple primary electron beams 220, and electron beam tool 140 may include a plurality of deflectors 204c to project the multiple primary electron beam 220 to different parts/sides of the wafer at the same time, to provide data for image reconstruction for different parts of wafer 203.

Exciting coil 204d and pole piece 204a generate a magnetic field that begins at one end of pole piece 204a and terminates at the other end of pole piece 204a. A part of wafer 203 being scanned by primary electron beam 220 may be immersed in the magnetic field and may be electrically charged, which, in turn, creates an electric field. The electric field reduces the energy of impinging primary electron beam 220 near the surface of wafer 203 before it collides with wafer 203. Control electrode 204b, being electrically isolated from pole piece 204a, controls an electric field on wafer 203 to prevent micro-arching of wafer 203 and to ensure proper beam focus.

A secondary electron beam 222 may be emitted from the part of wafer 203 upon receiving primary electron beam 220. Secondary electron beam 222 may form a beam spot on electron sensor surfaces 206a and 206b of electron detector 206. Electron detector 206 may generate a signal (e.g., a voltage, a current, etc.) that represents an intensity of the beam spot, and provide the signal to an image processing system 250. The intensity of secondary electron beam 222, and the resultant beam spot, may vary according to the external or internal structure of wafer 203. Moreover, as discussed above, primary electron beam 220 may be projected onto different locations of the top surface of the wafer or different sides of the wafer at a particular location, to generate secondary electron beams 222 (and the resultant beam spot) of different intensities. Therefore, by mapping the intensities of the beam spots with the locations of wafer 203, the processing system may reconstruct an image that reflects the internal or surface structures of wafer 203.

Imaging system 200 may be used for inspecting a wafer 203 on motorized sample stage 201, and comprises an electron beam tool 140, as discussed above. Imaging system 200 may also comprise an image processing system 250 that includes an image acquirer 260, storage 270, and controller 150. Image acquirer 260 may comprise one or more processors. For example, image acquirer 260 may comprise a computer, server, mainframe host, terminals, personal computer, any kind of mobile computing devices, and the like, or a combination thereof. Image acquirer 260 may connect with electron detector 206 of electron beam tool 140 through a medium such as an electrical conductor, optical fiber cable, portable storage media, IR, Bluetooth, internet, wireless network, wireless radio, or a combination thereof. Image acquirer 260 may receive a signal from electron detector 206 and may construct an image. Image acquirer 260 may thus acquire images of wafer 203. Image acquirer 260 may also perform various post-processing functions, such as generating contours, superimposing indicators on an acquired image, and the like. Image acquirer 260 may be configured to perform adjustments of brightness and contrast, etc. of acquired images. Storage 270 may be a storage medium such as a hard disk, cloud storage, random access memory (RAM), other types of computer readable memory, and the like. Storage 270 may be coupled with image acquirer 260 and may be used for saving scanned raw image data as original images, and post-processed images. Image acquirer 260 and storage 270 may be connected to controller 150. In some embodiments, image acquirer 260, storage 270, and controller 150 may be integrated together as one control unit.

In some embodiments, image acquirer 260 may acquire one or more images of a sample based on an imaging signal received from electron detector 206. An imaging signal may correspond to a scanning operation for conducting charged particle imaging. An acquired image may be a single image comprising a plurality of imaging areas. The single image may be stored in storage 270. The single image may be an original image that may be divided into a plurality of regions. Each of the regions may comprise one imaging area containing a feature of wafer 203.

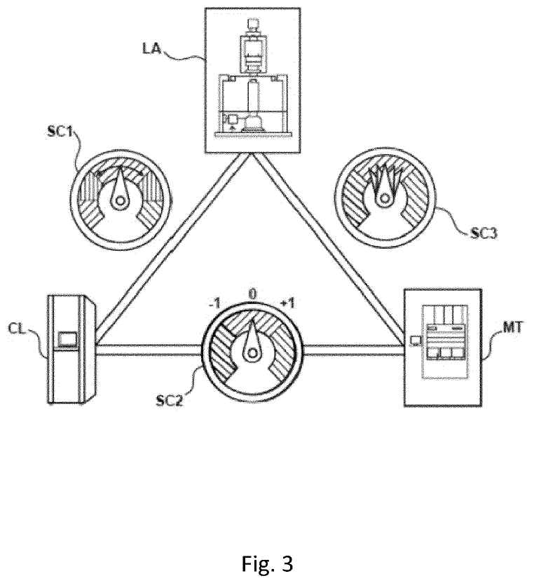

FIG. 3 depicts a schematic representation of holistic lithography, representing a cooperation between three technologies to optimize semiconductor manufacturing. Typically, the patterning process in a lithographic apparatus LA is one of the most critical steps in the processing which requires high accuracy of dimensioning and placement of structures on the substrate W (FIG. 1). To ensure this high accuracy, three systems (in this example) may be combined in a so called “holistic” control environment as schematically depicted in FIG. 3. One of these systems is the lithographic apparatus LA which is (virtually) connected to a metrology apparatus (e.g., a metrology tool) MT (a second system), and to a computer system CL (a third system). A “holistic” environment may be configured to optimize the cooperation between these three systems to enhance the overall process window and provide tight control loops to ensure that the patterning performed by the lithographic apparatus LA stays within a process window. The process window defines a range of process parameters (e.g., dose, focus, overlay) within which a specific manufacturing process yields a defined result (e.g., a functional semiconductor device)—typically within which the process parameters in the lithographic process or patterning process are allowed to vary.

The computer system CL may use (part of) the design layout to be patterned to predict which resolution enhancement techniques to use and to perform computational lithography simulations and calculations to determine which mask layout and lithographic apparatus settings achieve the largest overall process window of the patterning process (depicted in FIG. 2 by the double arrow in the first scale SC1). Typically, the resolution enhancement techniques are arranged to match the patterning possibilities of the lithographic apparatus LA. The computer system CL may also be used to detect where within the process window the lithographic apparatus LA is currently operating (e.g., using input from the metrology tool MT) to predict whether defects may be present due to, for example, sub-optimal processing (depicted in FIG. 2 by the arrow pointing “0” in the second scale SC2).

The metrology apparatus (tool) MT may provide input to the computer system CL to enable accurate simulations and predictions, and may provide feedback to the lithographic apparatus LA to identify possible drifts, e.g., in a calibration status of the lithographic apparatus LA (depicted in FIG. 3 by the multiple arrows in the third scale SC3).

In lithographic processes, it is desirable to make frequent measurements of the structures created, e.g., for process control and verification. Different types of metrology tools MT for making such measurements are known, including scanning electron microscopes or various forms of optical metrology tool, image based or scatterometery-based metrology tools. Image analysis on images obtained from optical metrology tools and scanning electron microscopes can be used to measure various dimensions (e.g., CD, overlay, edge placement error (EPE) etc.) and detect defects for the structures. In some cases, a feature of one layer of the structure can obscure a feature of another or the same layer of the structure in an image. This can be the case what one layer is physically on top of another layer, or when one layer is electronically rich and therefore brighter than another layer in a scanning electron microscopy (SEM) image, for example. In cases where a feature is partially obscured in an image, the location of the image can be determined based on template matching.

As used herein, the term “layer” refers to a process layer, e.g., a region of the printed object (e.g., a semiconductor device) that was created with the patterning processes. Layers can be made of different materials or may be different regions that are processed (e.g., when performing an etch, the area with material removed may be considered one layer and the area below it without material removed may be considered another layer).

As used herein, the term “overlay” (OVL) means a displacement between two layers. For example, two layers may be intended to have aligned centers (e.g., a top layer directly over a lower layer) but during manufacturing undesirably constructed with a shift between the two layers (e.g., an offset (or overlay) in the X and/or Y directions). In some cases, the overlay may be intentional, for example to test or calibrate equipment designed to measure or reduce the overlay.

The present disclosure provides numerous examples of maps having pixel counts, intensity values, plots with values in nanometers given for overlays, and other related features. These examples are intended only to aid in understanding of what is disclosed. The specific numerical values indicated are not intended to be automatically imparted into any particular embodiment should not be considered as limiting the present disclosure in any way.

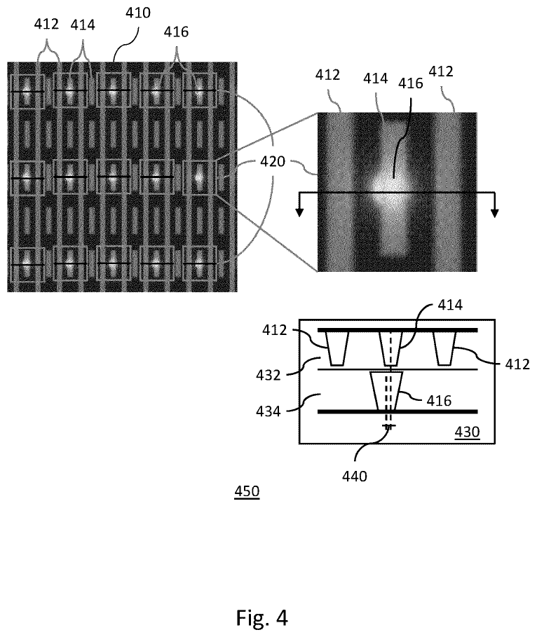

FIG. 4 illustrates an exemplary SEM image of a printed pattern having an overlay between two layers, according to an embodiment of the present disclosure. SEM image 410 is an example of image of a printed pattern and depicts numerous long bars 412, short bars 414 and vias 416. SEM image 410 depicts both surface features (long bars 412 and short bars 414) and features at a lower layer (vias 416) because SEMs obtain data not just from the top surface of an object but also from deeper within the object. Portions of SEM image 410 repeat and examples of such are depicted as unit cells 420. An expanded view of one unit cell 420 is provided to show some features in greater detail. Section A across the unit cell is taken in the downward direction and shown by inset 430. In section A, an upper layer 432 contains long bars 412 and a short bar 414 while lower layer 434 contains via 416. As depicted by inset 430, via 416 is not aligned with short bar 414. The displacement between the two layers (based on the centers of short bar 414 and via 416) is shown as OVL 440.

While the present disclosure refers to SEM images, it is contemplated that other imaging methods can be utilized, e.g., optical metrology, x-rays, etc. Also, such images are sometimes referred to herein generically as “multi-layer images” to represent any image that contains information about different layers which may have respective OVLs. It will be appreciated by people skilled in the art that multiple process layers can be disposed in the same depth or in different depth locations.

To determine the OVL of the pattern as a whole, the pixel intensity of the SEM image along lines (e.g., a particular row in a unit cell) can be utilized. Numerous intensity curves are depicted with some examples from some of the unit cells 420 indicated in SEM image 410. In some embodiments, for example to reduce the effects of noise, some unit cells can ostensibly be the same, but can have some minor differences due to the manufacturing process, etc. Such similar unit cells can be utilized to provide a representative sample for overlay determination. Accordingly, in some embodiments it can be advantageous to determine unit cells in the multi-layer image that represent a repeating portion of the multi-layer image. Then, the multi-layer image can be generated by averaging intensities of the multi-layer image in the unit cells.

The present disclosure provides various methods of determining OVL based on principal component analysis (PCA) of SEM images. To build a model that can accurately predict the OVL given input SEM data, different SEM images having known or programmed OVL can be obtained. The OVL may be the most prominent factor in the differences in the SEM images and PCA can thereby be utilized to capture this factor. For example, the coefficient of a certain principal component (e.g., represented by a function) can have a robust and even nearly linear relationship to the OVL. As such, a model can be built that utilizes the coefficient of this principal component to calculate the overlay. The model can be applied to a new SEM image by calculating coefficients for the corresponding principal component for the new SEM image and using those coefficients in the model to thereby output a predicted OVL for the new SEM image. In some embodiments, principal component scores can be obtained that can represent the image in a particular principal component space.

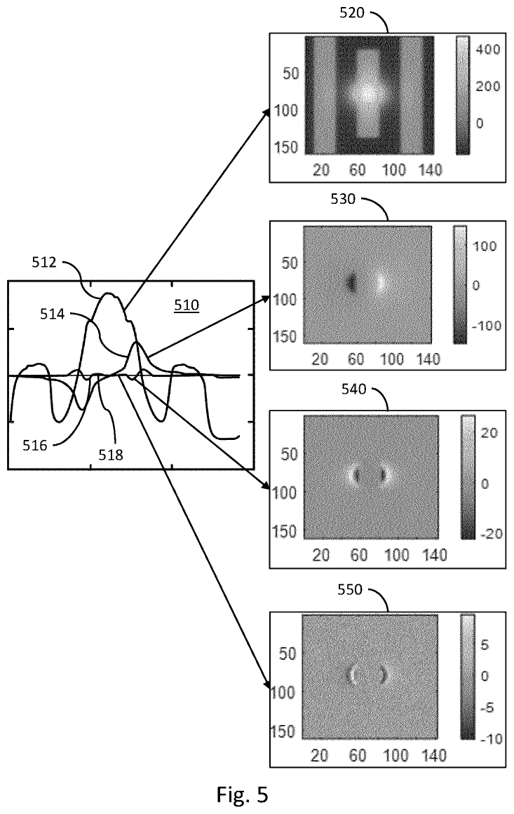

FIG. 5 illustrates performing principal component analysis on an SEM image, according to an embodiment of the present disclosure. As described in numerous embodiments throughout, component analysis (e.g., PCA) can be utilized to determine a finite set of components of a data set which, when taken together, closely approximate the original data set. This is expressed in Eq. 1, below, where SEM(x,y) is the original SEM image (or in the 1D case an intensity curve such as taken along a direction in a 2D image). Eq. 1 can be written as

$$SEM ( x , y ) = {\sum }_{i = 1}^{N} {PC}_{i} ( x , y ) * {Coeff}_{i} ( y ) . \qquad ( Eq . 1 )$$

Eq. 1 is written for the general 2D case, which can be considered a collection (in Y) of 1D PC arrays (in X). There can be maximum M number of principal component scores (PCᵢ), with their respective principal component coefficients (Coeffᵢ) allowing their sum to reproduce the SEM image, where M is the number of images used in PCA. For example, if 11 images (with 11 OVL values) are used for PCA, the maximum number of PCs is 11.

According to embodiments of the present disclosure, a set of SEM images of features with different programmed overlay values can be analyzed with PCA. For the depicted slice (e.g., along a certain line in the SEM image) through the example unit cells, the top four principal components (e.g., value vs. pixel position in X) are depicted in principal component plot 510 as a first principal component 512, second principal component 514, third principal component 516, and fourth principal component 518. In various embodiments, any number of principal components can be utilized. In some embodiments, the top N principal components can be selected such that together they are responsible for capturing the image and/or the variation in the image to a particular degree. In some embodiments, the component variances can be at least 90%, 95%, 99%, etc. of the multi-layer image. In some embodiments, this can be performed with the top three, four, five, etc. principal components, though any number of principal components can be utilized.

Images constructed from single principal components are also depicted in FIG. 5. For example, first image 520 depicts a reconstructed SEM image based only on first principal component 512. As seen, the features (e.g., bars, via) are clearly present and as such first principal component strongly reflects overall SEM signal. Second image 530 corresponds to second principal component 514, which is a next most dominant component after a first principal component that is the dominant principal component. While the main features are largely absent, second image 530 does depict two areas that reflect the OVL between the layers present in SEM image 400. As seen, the intensity of the second principal component 514 is significantly lower than the intensity of the first principal component 512 as it is not the dominant principal component. Similarly, third image 540 and fourth image 550 correspond to the third and fourth principal components, respectively. These images contain similar information to what is shown in second image 530 but with increasingly lower amplitudes as their contributions to SEM image 410 decrease.

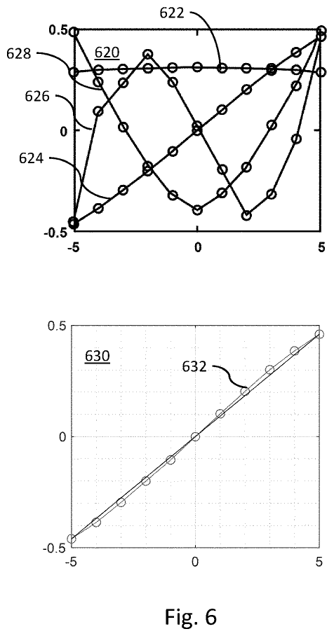

Component analysis can be utilized to determine an OVL accurately and computationally inexpensively from images. FIG. 6 illustrates determining an overlay based on principal component analysis, according to an embodiment of the present disclosure. In particular, the present disclosure contemplates embodiments where principal component analysis can be utilized to develop OVL models that can be used to determine OVL from SEM images. As described in further detail herein, one OVL model could be expressed as a function of the coefficients of various principal components. For example, a model can be in the form of

OVL=A Coeff³+B Coeff²+C Coeff¹+D. (Eq. 2)

In the example of Eq. 2, the OVL is a third-order polynomial fit to the values of a coefficient (coeff) determined from the principal component analysis (see, e.g., Eq. 1) and A-D are the parameters determined from the fitting. In some embodiments, the method can include determining principal components of the multi-layer image, determining variances (contributions to variations of the SEM image(s)) for the principal components of the multi-layer image, and can include determining that the selected components are some number of principal components having the largest variance and one or more successively lower variances. Here, coefficient plot 620 shows four curves that represent the coefficients (see, e.g., Eq. 1) for the top four principal components. However, coefficient plot 620 includes values of these coefficients at different set OVL values (e.g., −5 nm to +5 nm). The present disclosure contemplates that any principal component can be utilized to determine the OVL. Some principal components can be better suited to determining OVL than others. In some embodiments, certain Key Performance Indicators (KPI) or metrics such as flatness or sensitivity in predicting OVL can serve as the basis for selecting which principal component(s) to include in the OVL model. For example, the mirrored anti-symmetry of second coefficient curve 624 and fourth coefficient curve 628, and mirrored symmetry of third coefficient curve 626 can be used as weights to improve OVL estimation accuracy, as well as the KPI for OVL=0 estimation. As described herein, some embodiments can thereby incorporate model building with second coefficient curve 624 (being a main indicator of OVL) but other embodiments can also include third coefficient curve 626 and/or fourth coefficient curve 628 to refine OV estimation.

According to embodiments of the present disclosure, a method of building and/or applying an OVL model to determine an OVL can include performing a component analysis on a set of SEM images to obtain coefficients of one or more selected components, where the set of SEM images comprises a multi-layer image. As described previously, the selected components can be one or more principal components. The method can also include determining an OVL for the multi-layer image based on the coefficients.

In general, the set of images comprising a multi-layer image can be a single captured image, a composite image, a synthetic image, etc. Moreover, while some embodiments may utilize multiple SEM images to build an accurate OVL model, certain embodiments may utilize a single SEM image as an input for OVL determination if the single image contains the multiple same patterns but with different programmed overlay values.

The present disclosure provides a OVL model that correlates PCA results of a SEM image with OVL. The correlation can be achieved in any suitable method or form without departing from the scope of the present disclosure. In some embodiments, building the OVL model can include fitting a function of the selected principal component's coefficients at different OVLs and determining the function's parameters (such as A-D in Eq. 2). As previously mentioned, in some embodiments the method can include determining the OVL with a polynomial function of the coefficients of the one or more selected components, with a lookup table containing coefficients of the one or more selected components, etc. Functions that are polynomials of any order may be utilized, with particular polynomials (e.g., odd order, 3^{rd} order, 5^{th} order), being particularly advantages for some patterns and/or to avoid overfitting. In other embodiments, any other suitable math functions can be utilized for fitting, for example, trigonometric functions, etc. Coefficient fit plot 630 depicts second coefficient curve 624 with a polynomial fit 632 through the points (and a linear fit shown for comparison). Further details and examples of polynomial fitting determine coefficients are described.

While some embodiments can utilize a single principal component, for example the system determining which principal component is single-valued or has the highest sensitivity (such as second coefficient curve 624), other embodiments can perform building an OVL model based on multiple principal components. Three examples of methods utilizing multiple principal components are provided below.

As a first example, some embodiments can include obtaining a number of multi-layer images (e.g., 11 SEM images). The coefficients for the multi-layer images can be determined from the component analysis, for example using any of the methods described herein, and different OVLs can be determined (e.g., by accessing the programmed OVLs for the multi-layer images) for the multi-layer images. The OVL model can be generated based on the coefficients and the different OVLs. This embodiment can be further described with reference to Eq. 3, showing an N by M matrix (N being the selected number of principal components and M being the number of multi-layer images) and the right hand side showing the M different OVLs (e.g., programmed OVLs):

$$( \begin{matrix}{Coef}_{1 , 1} & {Coef}_{1 , 2} & {Coef}_{1 , 3} & {Coef}_{1 , 4} \\ {Coef}_{2 , 1} & {Coef}_{2 , 2} & {Coef}_{2 , 3} & {Coef}_{2 , 4} \\ {Coef}_{3 , 1} & {Coef}_{3 , 2} & {Coef}_{3 , 3} & {Coef}_{3 , 4} \\ ⋮ & ⋮ & ⋮ & ⋮ \\ {Coef}_{11 , 1} & {Coef}_{11 , 2} & {Coef}_{11 , 3} & {Coef}_{11 , 4}\end{matrix} ) ( \begin{matrix}{x}_{1} \\ {x}_{2} \\ {x}_{3} \\ {x}_{4}\end{matrix} ) = ( \begin{matrix}{OVL}_{1} \\ {OVL}_{2} \\ {OVL}_{3} \\ ⋮ \\ {OVL}_{11}\end{matrix} ) . \qquad Eq . 3$$

By solving Eq. 3 for the X vector, the X vector can be utilized as part of the OVL model. To apply the OVL model, coefficients can be determined for the principal components of the test image and utilized with the X vector determined from Eq. 3 to generate an estimated OVL. For example, embodiments of applying the OVL model can include obtaining a test SEM image, determining test coefficients for the test SEM image by performing component analysis on the test SEM image, and determining a test OVL for the test SEM image based on applying the OVL model with the test coefficients.

As a second example, some embodiments can include assigning weights to the coefficients. This is depicted by Eq. 4:

$$( \begin{matrix}{Coef}_{1 , 1} * {w}_{1} & {Coef}_{1 , 2} * {w}_{2} & {Coef}_{1 , 3} * {w}_{3} & {Coef}_{1 , 4} * {w}_{4} \\ {Coef}_{2 , 1} * {w}_{1} & {Coef}_{2 , 2} * {w}_{2} & {Coef}_{2 , 3} * {w}_{3} & {Coef}_{2 , 4} * {w}_{4} \\ {Coef}_{3 , 1} * {w}_{1} & {Coef}_{3 , 2} * {w}_{2} & {Coef}_{3 , 3} * {w}_{3} & {Coef}_{3 , 4} * {w}_{4} \\ ⋮ & ⋮ & ⋮ & ⋮ \\ {Coef}_{11 , 1} * {w}_{1} & {Coef}_{11 , 2} * {w}_{2} & {Coef}_{11 , 3} * {w}_{3} & {Coef}_{11 , 4} * {w}_{4}\end{matrix} ) ( \begin{matrix}{x}_{1} \\ {x}_{2} \\ {x}_{3} \\ {x}_{4}\end{matrix} ) = ( \begin{matrix}{OVL}_{1} \\ {OVL}_{2} \\ {OVL}_{3} \\ ⋮ \\ {OVL}_{11}\end{matrix} ) . \qquad Eq . 4$$

In some embodiments, the weights can be determined based on an intensity level of the selected components (see, e.g., examples of principal component images depicted in FIG. 5). The application of the OVL model built in this example is similar to that in the first example. In some embodiments, the application can include obtaining a test SEM image, determining test coefficients for the test SEM image by performing component analysis on the test SEM image, assigning test weights to the test coefficients, and determining a test OVL for the test SEM image based on applying the OVL model with the test coefficients and the test weights.

As a third example, rather than Eq. 3 having an N×M matrix of coefficients, an N-sized vector can be utilized that includes functions that are fits to the selected components (see, e.g., polynomial fit 632 in FIG. 6). Accordingly, some embodiments can include methods of fitting functions to the coefficients of the selected components, where the OVL model can be generated based on the coefficients, the different OVLs, and the functions. This is depicted in Eq. 5, below, showing the fitted functions represented by “fun1,” “fun2,” etc. to form the N-sized vector, which with the programmed OVLs can be utilized to solve for the X-vector for the OVL model:

$$\begin{matrix}( fun 1 & fun 2 & fun 3 & fun 4 )\end{matrix} ( \begin{matrix}{x}_{1} \\ {x}_{2} \\ {x}_{3} \\ {x}_{4}\end{matrix} ) = ( \begin{matrix}{OVL}_{1} \\ {OVL}_{2} \\ {OVL}_{3} \\ ⋮ \\ {OVL}_{11}\end{matrix} ) . \qquad Eq . 5$$

Applying the OVL model generated in this way can include obtaining a test SEM image, determining test coefficients for the test SEM image by performing component analysis on the test SEM image, inputting the test coefficients into the functions, and determining a test OVL for the test SEM image based on applying the OVL model with the functions. In some embodiments, the X vector can be calculated by performing an optimization method to minimize a difference between two sides of Eq. 5.

The present disclosure provides a detailed description of the component analysis being a principal component analysis. However, in some embodiments, other methods can be utilized such as independent component analysis. Also, the component analysis can be performed along any direction in the image. However, in some embodiments (e.g., as suggested by section A in FIG. 4), the component analysis is along a direction of the OVL in the multi-layer image. Also, as described herein, the component analysis can be applied to any image, with embodiments given as examples where the component analysis is of a two-dimensional multi-layer image.

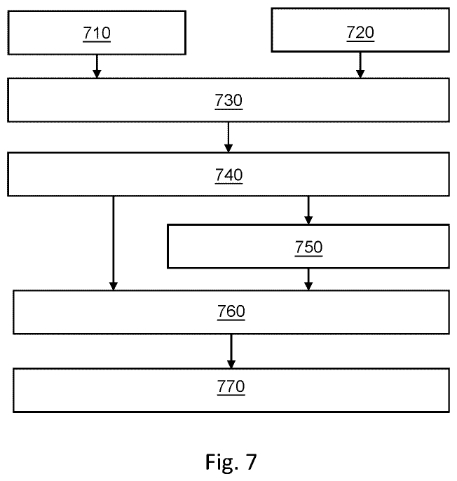

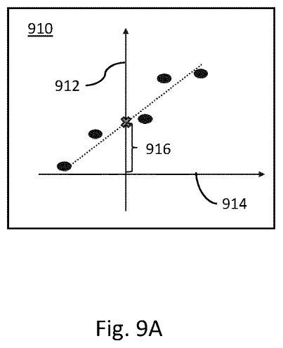

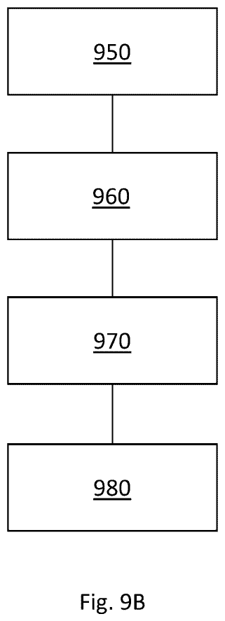

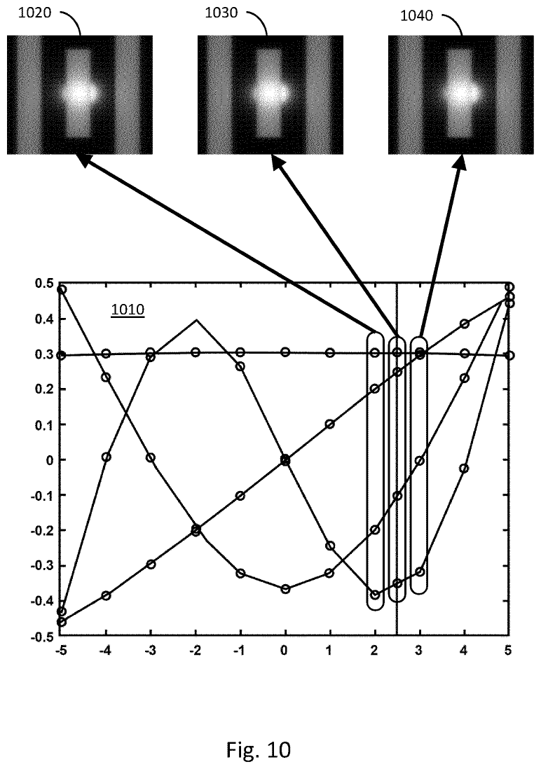

FIG. 7 illustrates a process flow diagram for building an overlay model, according to an embodiment of the present disclosure. At 710, one or more images (e.g., SEM images) can be obtained that together comprise a multi-layer image. At 720, the respective programmed OVLs of the features presented in the images (e.g., set OVL) can be input to associate a specific SEM image with a programmed OVL (see, e.g., the discussion surrounding FIG. 6). At 730, unit cell image averaging be performed, for example, to combine like images or portions thereof and thereby effectively reducing the effect of noise. At this stage (or independently), the process can also include determining a region of interest over which the component analysis/coefficient determination can be performed. At 740, component analysis can be performed to determine the principal components and also to perform functional fitting that can be used to build the OVL model (see, e.g., the discussion surrounding FIG. 6). In some embodiments, the process can include at 750, determining the intercept associated with the OVL model (see, e.g., the discussion surrounding FIGS. 9 and 10). At 760, the OVL model can be built utilizing the selected coefficients and/or the intercept (see, e.g., the discussion surrounding FIGS. 6 and 9). At 770, the OVL model can be adjusted based on further processes such as determining OVL shifts from asymmetries (see, e.g., the discussion surrounding

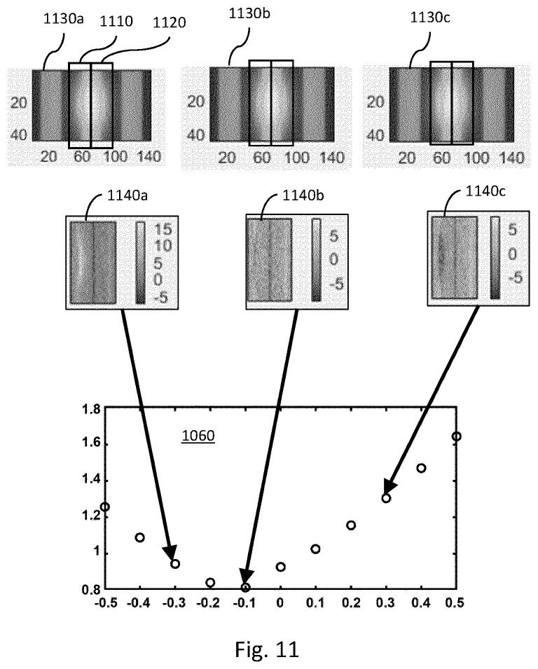

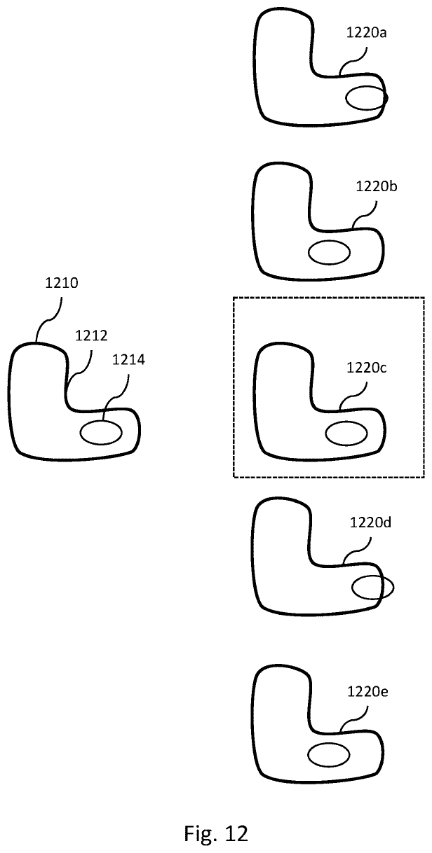

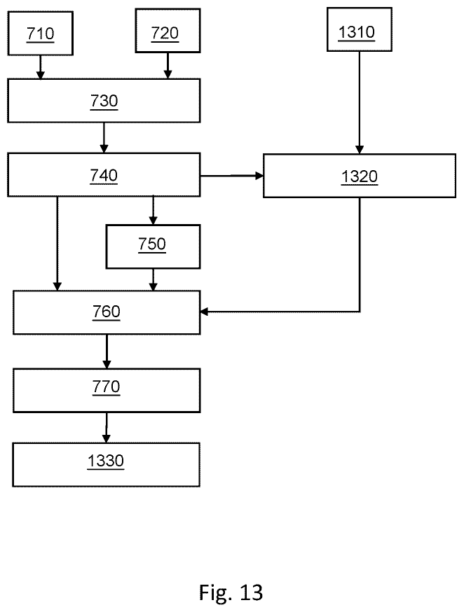

FIG. 11) or from pattern matching (see., e.g., the discussion surrounding FIG. 12). Detailed embodiments for applying the OVL model are also provided as discussed herein, with particular reference to FIG. 13.

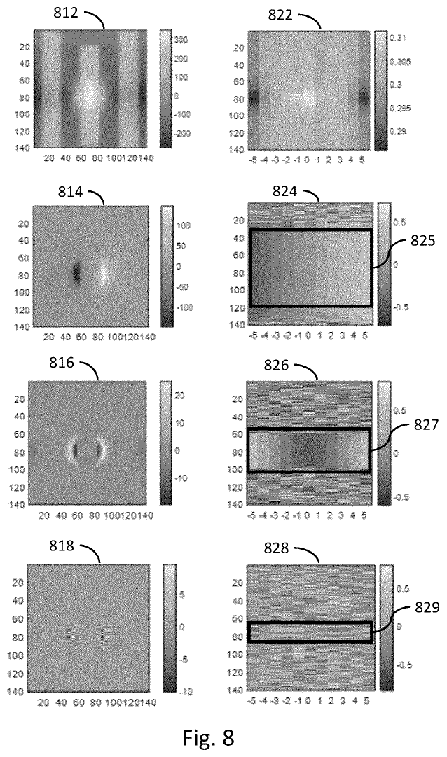

FIG. 8 illustrates regions of interest utilized in determining coefficients for an OVL model, according to an embodiment of the present disclosure. In various embodiments, 2D analysis (as opposed to 1D analysis along a single line in the multi-layer image) can provide improved OVL model accuracy by including a greater amount of usable data. However, the usable portions of the data providing the coefficients can depend on several factors such as, for example, the size of a unit cell (or the images used), the size and geometry of the features present in the multilayer image that are relied upon to provide indications of the OVL, etc. The left column of plots in FIG. 8 depicts examples of images (812, 814, 816, 818) of the first, second, third, and fourth principal components, respectively. Images similar to those shown above but with different OVLs (e.g., having different set OVLs such as from −5 nm to +5 nm) can be utilized to generate a 2D coefficient map. This is analogous to a 2D version of coefficient plot 620 in FIG. 6. Four corresponding examples of coefficient maps (822, 824, 826, 828) are shown in the right column of plots in FIG. 8, with the horizontal axis being the set OVL, the vertical axis being the row from the corresponding SEM image, and the value being the coefficient.

Having such additional data can improve model robustness. In some embodiments, not all 2D data are used. In the case of coefficient map 822, generated from the first principal component, variations in the values of intensity are observed but appear to be coherent everywhere (i.e., not strongly affected by noise). For coefficient map 824, a region of coherence 825 (also referred to herein as a region of interest) is observed near the middle of the map. However, regions of incoherence (i.e., noisy) appear away from where the SEM image may be expected to obtain signal reflective of an overlay (e.g., where the short bar and via overlap). Accordingly, some embodiments can include obtaining the coefficients in a region of interest of the SEM image where the region of interest has a lower noise contribution than other regions in the multi-layer image. Similar regions of interest 827 and 829 are shown for coefficient maps 826 and 828. Accordingly, the coefficient maps indicate that the interaction region where the SEM data can provide data useful for determining the OVL is not limited to, and in fact can extend far beyond, the specific locations where features may overlap. The coefficient maps also indicate that such regions of interest can become smaller with less dominant principal components.

FIG. 9A is a diagram illustrating an overlay shift, according to an embodiment of the present disclosure. OVL plot 910 depicts a simplified example of actual overlays 912 as a function of a set overlay 914. For example, various patterns can be manufactured to have (or expected to have) a particular overlay (referred to herein as “set OVL”). However, due to stochastic or other manufacturing processes, the actual overlay that the measurements get (referred to herein as “get OVL”) may vary slightly as compared to an expected OVL. In general, it is expected that the relationship between the two is linear (e.g., a set OVL of +1.0 nm has a get OVL of 1.0 nm, a set OVL of +2.0 nm has a get OVL of 2.0 nm, etc.). A simplified OVL model that captures this relationship is shown in FIG. 9A by the linear fit through the measured OVLs. However, in practice, there may be an offset or shift, which if determined properly, can be utilized to allow an OVL model to better predict the get OVL given the set OVL. This offset (also referred to herein as “intercept” 916) is depicted in OVL plot 910.

FIG. 9B is a process flow diagram illustrating determining an overlay shift, according to an embodiment of the present disclosure. The OVL model can be improved by accurately determining an OVL shift (e.g., intercept 916 in FIG. 9A) for an OVL curve. FIGS. 9B-12 describe various embodiments for determining the OVL shift. The overall process shown in FIG. 9B can include, at 950, determining an intercept search range. For example, the intercept search range can be determined based on a wafer manufacturing process or based on a measured OVL value from a different OVL algorithm. For example, for an advanced layer, the intercept can be within +/−3 nm. As another example, the intercept can be estimated from a different OV algorithm can be within +/−2~3 nm from the true intercept value. At 960, for one or more intercepts in the search range, the method can include determining interpolated coefficients by interpolating the coefficients of the coefficient curves for the selected (e.g., top N) components at intercept values in the intercept search range. In some embodiments, this can include generating assembled images based on the interpolated coefficients, where the assembled images have corresponding OVL shifts. At 970, an OVL shift can be determined based on the assembled images. At 980, the OVL for the multi-layer image can be modified based on the OVL shift.

FIG. 10 illustrates generating assembled images having respective overlay shifts, according to an embodiment of the present disclosure. Coefficient plot 1010 depicts an example of coefficients for four principal components as a function of set OV. The determining of the interpolated coefficients at the intercept value can include interpolating over the coefficients (e.g., obtained from the available set of SEM images) within the intercept search range (e.g., +0.5 nm) of OVL shifts (e.g., in 0.1 nm increments: −0.5, −0.4, . . . +0.5 nm). In various embodiments, other search ranges (e.g., ±3, 10, 20 nm, etc.) and/or increments (e.g., 0.05, 0.2, 0.3 nm, etc.) can be utilized. The circled coefficients for set OVL of +2.0 and +3.0 are shown circled, with interpolated coefficients for set OVL of 2.5 nm determined for this example. In this way, the disclosed methods can provide coefficients at a desired set OVL. Also shown are images that can be reconstructed from the principal components utilizing the depicted coefficients corresponding to a particular OVL. Image 1020 corresponds to an OVL of 2 nm, image 1030 corresponds to an OVL of 2.5 nm, and image 1040 response to an OVL of 3 nm. these assembled images can have a lower noise level because the selected top N PCs mainly contain the OV-related information, which excludes most of the noise contributions. The lower noise level in assembled images can thus further benefit the OV shift finding algorithms as disclosed herein.

FIG. 11 illustrates determining an overlay shift based on asymmetries in symmetric assembled images, according to an embodiment of the present disclosure. For symmetric images (e.g., of the sort depicted in unit cells in FIG. 4), an overlay shift can be determined by finding an asymmetry in a portion of the assembled image. For example, with the assembled images corresponding to OVL shifts in the search range, the determining of the OVL shift can include the following. First regions 1110 and second regions 1120 can be selected in assembled images 1130a-c, with the first regions 1110 and second regions 1120 being of equal extents about respective centers of the assembled images 1130a-c. Asymmetry scores 1140a-c of the assembled images can be determined by, for example, taking the differences of the images in the first regions 1110 or second regions 1120. The asymmetry scores can then be calculated as, for example, the absolute value of the mean of the differences. In other embodiments, other metrics can be utilized to quantify the degree of asymmetry and arrive at asymmetry scores. The method can then include setting the OVL shift based on the assembled image with the lowest asymmetry score. This is illustrated in plot 1160 showing calculated asymmetry scores for a number of assembled images having OVL shifts. The points (OVLs) corresponding to the examples of assembled images 1130a-c are indicated by the arrows. In this example, assembled image 1130b has the lowest asymmetry score 1140b and so its corresponding OVL (−0.1 nm) would be taken as the OVL shift.

FIG. 12 illustrates determining an overlay shift based on asymmetric assembled images, according to an embodiment of the present disclosure. In some embodiments, the features in the unit cell or otherwise being used for determination of the OVL may not be symmetric. To find the OVL shift for such images, some methods can include generating a template image 1210 for the multi-layer image (or portion thereof), the template image 1210 generated to have an OVL shift of zero. This is depicted in FIG. 12 by the template image 1210 on the left that indicates an “L-shaped” bar 1212 and a via 1214 as could be discerned from a multi-layer image. The method can also include comparing the template image to assembled images 1220a-e. These assembled images can be generated as described with reference to FIG. 10, for example by interpolating over curves for OVL coefficients. The method can then include setting the OVL shift to be the corresponding OVL shift for the assembled image that is a best match to the template image. In some embodiments, the best match can be determined by template matching or image differencing. This is seen in FIG. 12 where assembled image 1220c is the best match to template image 1210.

FIG. 13 is a process flow diagram illustrating application of an OVL model, according to an embodiment of the present disclosure. Various embodiments described herein have detailed how an accurate OVL model can be built utilizing component analysis of SEM images. With such OVL model(s), they can then be applied to determine OVLs of test images. In FIG. 13, the process diagram from FIG. 7 is reproduced to show how the model application relates to the built OVL model. For example, in some embodiments, a method can include, at 1310, obtaining an SEM test image. In some embodiments, unit cell averaging and region of interest selection can be performed similar to that previously described herein. At 1320, the test coefficients of the SEM test image can be determined based on one or more selected components. These test coefficients can be put back into the built OVL model to predict the OVL for the SEM test image. At 1330, an OVL of the SEM test image can be determined based on applying an OVL model with the test coefficients.

In some embodiments, applying the OVL model to a test image can include generating new coefficients for selected principal components based on the test image. For example, a method can include determining the test coefficients based on linear regression of an SEM test image and the selected components. An example of such linear regression is

Y=XB. (Eq. 6)

In Eq. 6, Y is a matrix representing the SEM test image, X is a matrix representing the principal components in the OV model, and B are the coefficients that would produce the SEM test image. Written in matrix form, Eq. 6 becomes

$$[ \begin{matrix}{y}_{1} \\ {y}_{2} \\ ⋮ \\ {y}_{N}\end{matrix} ] = [ \begin{matrix}1 & {x}_{1} \\ 1 & {x}_{2} \\ ⋮ & ⋮ \\ 1 & {x}_{N}\end{matrix} ] [ \begin{matrix}{β}_{1} \\ {β}_{2}\end{matrix} ] . \qquad ( Eq . 7 )$$

The matrix equation of Eq. 7 can be solved by linear regression or any optimization method for the test coefficients B, which can be put into the OV model as shown in FIG. 13. The applied OVL model can then output, at 1330, a predicted OVL for the SEM test image.

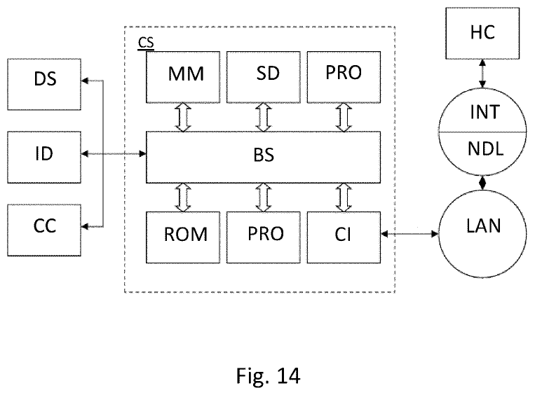

FIG. 14 is a block diagram of an example computer system CS, according to an embodiment of the present disclosure.

Computer system CS includes a bus BS or other communication mechanism for communicating information, and a processor PRO (or multiple processor) coupled with bus BS for processing information. Computer system CS also includes a main memory MM, such as a random access memory (RAM) or other dynamic storage device, coupled to bus BS for storing information and instructions to be executed by processor PRO. Main memory MM also may be used for storing temporary variables or other intermediate information during execution of instructions to be executed by processor PRO. Computer system CS further includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a cathode ray tube (CRT) or flat panel or touch panel display for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

According to one embodiment, portions of one or more methods described herein may be performed by computer system CS in response to processor PRO executing one or more sequences of one or more instructions contained in main memory MM. Such instructions may be read into main memory MM from another computer-readable medium, such as storage device SD. Execution of the sequences of instructions contained in main memory MM causes processor PRO to perform the process steps described herein. One or more processors in a multi-processing arrangement may also be employed to execute the sequences of instructions contained in main memory MM. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have instructions recorded thereon. The instructions, when executed by a computer, can implement any of the features described herein. Transitory computer-readable media can include a carrier wave or other propagating electromagnetic signal.

Various forms of computer readable media may be involved in carrying one or more sequences of one or more instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) both use electrical, electromagnetic or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN and communication interface CI. One such downloaded application may provide all or part of a method described herein, for example. The received code may be executed by processor PRO as it is received, and/or stored in storage device SD, or other non-volatile storage for later execution. In this manner, computer system CS may obtain application code in the form of a carrier wave.

Embodiments of the present disclosure can be further described by the following clauses.
1. A method comprising:
   performing a component analysis on a set of Scanning Electron Microscope (SEM) images to obtain coefficients of one or more selected components in the component analysis, wherein the set of SEM images comprises a multi-layer image; and
   determining an overlay (OVL) for the multi-layer image based on the coefficients.
2. The method of clause 1, wherein the OVL is determined with a polynomial function of the coefficients of the one or more selected components.
3. The method of clause 1, wherein the OVL is determined with a lookup table containing coefficients of the one or more selected components.
4. The method of clause 1, wherein the component analysis is a Principal Component Analysis (PCA).
5. The method of clause 1, wherein the component analysis is an Independent Component Analysis (ICA).
6. The method of clause 1, wherein the component analysis is along a direction of the OVL in the multi-layer image.
7. The method of clause 1, wherein the component analysis is of a two-dimensional multi-layer image.
8. The method of clause 1, further comprising:
   determining unit cells in the multi-layer image that represent a repeating portion of the multi-layer image; and
   generating the multi-layer image by averaging intensities of the multi-layer image in the unit cells.
9. The method of clause 1, further comprising obtaining the coefficients in a region of interest of the SEM image, the region of interest having a lower noise contribution than other regions in the multi-layer image.
10. The method of clause 1, the method comprising:
   determining principal components of the multi-layer image;
   determining variances for principal components of the multi-layer image; and
   determining the one or more selected components to be a plurality of the principal components having a largest variance and one or more successively lower variances.
11. The method of clause 5, wherein the one or more selected components are responsible for component variances at least 95% of the multi-layer image.
12. The method of clause 5, wherein the one or more selected components include a second principal component, which is a next most dominant component after a first principal component that is the dominant principal component.
13. The method of clause 5, further comprising:
   building an OVL model to determine the OVL based on the coefficients, the building comprising fitting a function to determine parameters of the function based on values of the one or more selected components at different OVLs.
14. The method of clause 6, wherein the function is an odd order polynomial.
15. The method of clause 7, wherein the function is a third order polynomial or a fifth order polynomial.
16. The method of clause 6, further comprising:
   obtaining a plurality of multi-layer images;
   determining the coefficients from the component analysis for the plurality of multi-layer images;
   obtaining the different OVLs for the plurality of multi-layer images; and
   generating the OVL model based on the coefficients and the different OVLs.
17. The method of clause 8, further comprising applying the OVL model by:
   obtaining a test SEM image;
   determining test coefficients for the test SEM image by performing component analysis on the test SEM image; and
   determining a test OVL for the test SEM image based on applying the OVL model with the test coefficients.
18. The method of clause 8, further comprising assigning weights to the coefficients.
19. The method of clause 9, wherein the weights are determined based on an intensity level of the one or more selected components.
20. The method of clause 9, further comprising applying the OVL model by:
   obtaining a test SEM image;
   determining test coefficients for the test SEM image by performing component analysis on the test SEM image;
   assigning test weights to the test coefficients; and
   determining a test OVL for the test SEM image based on applying the OVL model with the test coefficients and the test weights.
21. The method of clause 8, further comprising fitting functions to the coefficients of the one or more selected components, wherein the OVL model is generated based on the coefficients, the different OVLs, and the functions.
22. The method of clause 11, further comprising applying the OVL model by:
   obtaining a test SEM image;
   determining test coefficients for the test SEM image by performing component analysis on the test SEM image;
   inputting the test coefficients into the functions; and
   determining a test OVL for the test SEM image based on applying the OVL model with the functions.
23. The method of clause 1, further comprising:
   determining an intercept search range;
   determining interpolated coefficients by interpolating the coefficients of coefficient curves for the selected components at intercept values in the intercept search range;
   generating assembled images based on the interpolated coefficients, the assembled images having corresponding OVL shifts;
   determining an OVL shift based on the assembled images; and
   modifying the OVL for the multi-layer image based on the OVL shift.
24. The method of clause 12, the determining of the interpolated coefficients at the intercept values comprising interpolating over the coefficients within the intercept search range (e.g., +0.5 nm) of the OVL shifts.
25. The method of clause 12, the determining of the OVL shift comprising:
   selecting first regions and second regions of the assembled images, the first regions and second regions being of equal extents about respective centers of the assembled images;
   determining asymmetry scores of the assembled images; and
   setting the OVL shift based on the assembled image with the lowest asymmetry score.
26. The method of clause 12, further comprising:
   generating a template image for the multi-layer image, the template image generated to have an OVL shift of zero;
   comparing the template image to the assembled images; and
   setting the OVL shift to be the corresponding OVL shift for the assembled image that is a best match to the template image.
27. The method of clause 15, wherein the best match is determined by template matching or image differencing.
28. The method of clause 1, further comprising:
   obtaining an SEM test image;
   determining test coefficients of the SEM test image based on the one or more selected components; and
   determining an OVL of the test image based on applying OVL model with the test coefficients.
29. The method of clause 28, further comprising determining the test coefficients based on linear regression of an SEM test image and the selected components.
30. A non-transitory computer readable medium having instructions recorded thereon for a lithographic process, the instructions when executed by a computer having at least one programmable processor cause operations comprising, the operations as in any of clauses 1-29.
31. A system for use with a lithographic process, the system comprising:
   at least one programmable processor; and
   a non-transitory computer readable medium having instructions recorded thereon, the instructions when executed by a computer having the at least one programmable processor cause operations as in any of clauses 1-29.

The combinations and sub-combinations of the elements disclosed herein constitute separate embodiments and are provided as examples only. Also, the descriptions above are intended to be illustrative, not limiting. Thus, it will be apparent to one skilled in the art that modifications may be made as described without departing from the scope of the claims set out below.

1. A non-transitory computer readable medium having instructions recorded thereon or therein, the instructions, when executed by at least one programmable processor, are configured to cause the at least one programmable processor to at least:
perform a component analysis on a set of Scanning Electron Microscope (SEM) images of a substrate manufactured by a lithographic process to obtain coefficients of one or more selected components in the component analysis, wherein the set of SEM images comprises a multi-layer image; and
determine an overlay (OVL) for the multi-layer image based on the coefficients.

2. The medium of claim 1, wherein the OVL is determined by use of a polynomial function of the coefficients of the one or more selected components, or by using a lookup table containing coefficients of the one or more selected components.

3. The medium of claim 1, wherein the component analysis is a Principal Component Analysis (PCA) or an Independent Component Analysis (ICA), wherein the component analysis is performed along a direction of the OVL in the multi-layer image.

4. The medium of claim 1, wherein the instructions are further configured to cause the at least one programmable processor to obtain the coefficients in a region of interest of the multi-layer image, the region of interest having a lower noise contribution than other regions in the multi-layer image.

5. The medium of claim 1, wherein the instructions are further configured to cause the at least one programmable processor to:
determine principal components of the multi-layer image;
determine variances for principal components of the multi-layer image; and
determine the one or more selected components to be a plurality of the principal components having a largest variance and one or more successively lower variances.

6. The medium of claim 1, wherein the instructions are further configured to cause the at least one programmable processor to build an OVL model to determine the OVL based on the coefficients, wherein the instructions configured to cause the at least one programmable processor to build the OVL model are further configured to cause the at least one programmable processor to fit a function to determine parameters of the function based on values of the one or more selected components at different OVLs.

7. The medium of claim 6, wherein the function is an odd order polynomial.

8. The medium of claim 6, wherein the instructions are further configured to cause the at least one programmable processor to:
obtain a plurality of multi-layer images;
determine the coefficients from the component analysis for the plurality of multi-layer images;
obtain the different OVLs for the plurality of multi-layer images; and
generate the OVL model based on the coefficients and the different OVLs.

9. The medium of claim 6, wherein the instructions are further configured to cause the at least one programmable processor to assign weights to the coefficients.

10. The medium of claim 9, wherein the weights are determined based on an intensity level of the one or more selected components.

11. The medium of claim 6, wherein the instructions are further configured to cause the at least one programmable processor to fit functions to the coefficients of the one or more selected components, wherein the OVL model is generated based on the coefficients, the different OVLs, and the functions.

12. The medium of claim 1, wherein the instructions are further configured to cause the at least one programmable processor to:
determine an intercept search range;
determine interpolated coefficients by interpolating the coefficients of coefficient curves for the selected components at intercept values in the intercept search range;
generate assembled images based on the interpolated coefficients, the assembled images having corresponding OVL shifts;
determine an OVL shift based on the assembled images; and
modify the OVL for the multi-layer image based on the OVL shift.

13. The medium of claim 12, wherein the determination of the interpolated coefficients at the intercept values comprises interpolation over the coefficients within the intercept search range of the OVL shifts.

14. The medium of claim 12, wherein the instructions configured to cause the at least one programmable processor to determine the OVL shift are further configured to cause the at least one programmable processor to:
select first regions and second regions of the assembled images, the first regions and second regions being of equal extents about respective central portions of the assembled images;
determine asymmetry scores of the assembled images; and
set the OVL shift based on the assembled image with the lowest asymmetry score.

15. The medium of claim 12, wherein the instructions are further configured to cause the at least one programmable processor to:
generate a template image for the multi-layer image, the template image generated to have an OVL shift of zero;
compare the template image to the assembled images; and
set the OVL shift to be the corresponding OVL shift for the assembled image that is a best match to the template image.

16. A method comprising:
obtaining a set of Scanning Electron Microscope (SEM) images;
performing a component analysis on the set of Scanning Electron Microscope (SEM) images to obtain coefficients of one or more selected components in the component analysis, wherein the set of SEM images comprises a multi-layer image; and
determining, by a hardware processor system, an overlay (OVL) for the multi-layer image based on the coefficients.

17. The method of claim 16, wherein the OVL is determined using a polynomial function of the coefficients of the one or more selected components, or by using a lookup table containing coefficients of the one or more selected components.

18. The method of claim 16, wherein the component analysis is a Principal Component Analysis (PCA) or an Independent Component Analysis (ICA), wherein the component analysis is performed along a direction of the OVL in the multi-layer image.

19. The method of claim 16, further comprising obtaining the coefficients in a region of interest of the multi-layer image, the region of interest having a lower noise contribution than other regions in the multi-layer image.

20. The method of claim 16, further comprising:
determining principal components of the multi-layer image;
determining variances for principal components of the multi-layer image; and
determining the one or more selected components to be a plurality of the principal components having a largest variance and one or more successively lower variances.
